(19) United States
(12) Patent Application Publication
(10) Pub. No.: US 2026/0081702 A1
(43) Pub. Date: Mar. 19, 2026

(54) Wireless Circuitry with Amplifier Variation Mitigation

(71) Applicant: Apple Inc., Cupertino, CA (US)

(72) Inventors: Mohammad B Vahid Far, San Jose, CA (US); Brian B Whitaker, Los Gatos, CA (US)

(21) Appl. No.: 18/887,962

(22) Filed: Sep. 17, 2024

(51) Int. Cl. H04B 17/13; H03F 3/24; H04B 1/04

(52) U.S. Cl. CPC H04B 17/13; H03F 3/245; H04B 1/0483; H03F 2200/451

(57) ABSTRACT

An electronic device may include a transmitter coupled to an antenna over a signal path that runs through a front end module. The front end module may include a power amplifier disposed on the signal path. The front end module may include first, second, and/or third signal attenuators disposed on the signal path between an input of the amplifier and the transmitter. The front end module may include a voltage sensor that measures a bias voltage of the amplifier, a temperature that measures a temperature of the amplifier, and/or an impedance sensor that measures an impedance of the antenna. The first signal attenuator may be adjusted based on the measured bias voltage, the second signal attenuator may be adjusted based on the measured temperature, and the third signal attenuator may be adjusted based on the measured impedance to mitigate changes in the amplifier as operating conditions change over time.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry. The wireless communications circuitry includes a signal path that conveys a radio-frequency signal. Amplifiers on the signal path amplify the radio-frequency signal. It can be challenging to provide amplifiers with sufficient levels of performance across all operating conditions of the wireless communications circuitry.

### SUMMARY

An electronic device may include wireless circuitry. The wireless circuitry may include a transmitter coupled to an antenna over a signal path that runs through a front end module. The front end module may include a power amplifier disposed on the signal path. The front end module may include first, second, and/or third signal attenuators disposed on the signal path between an input of the power amplifier and the transmitter.

The front end module may include a voltage sensor that measures a bias voltage of the power amplifier, a temperature that measures a temperature of the power amplifier, and/or an impedance sensor that measures an impedance of the antenna. The first signal attenuator may be adjusted based on the measured bias voltage, the second signal attenuator may be adjusted based on the measured temperature, and the third signal attenuator may be adjusted based on the measured impedance to mitigate changes in the saturation power of the power amplifier even as operating conditions change over time.

An aspect of the disclosure provides wireless circuitry. The wireless circuitry can include a signal source. The wireless circuitry can include an output load. The wireless circuitry can include a signal path that couples the signal source to the output load, the signal source being configured to transmit a radio-frequency signal to the output load over the signal path. The wireless circuitry can include an amplifier on the signal path and configured to amplify the radio-frequency signal. The wireless circuitry can include first and second signal attenuators on the signal path between the signal source and the amplifier. The wireless circuitry can include a voltage sensor configured to measure a bias voltage of the amplifier, wherein the first signal attenuator exhibits a first attenuation level that is adjusted based on the measured bias voltage. The wireless circuitry can include a temperature sensor configured to measure a temperature of the amplifier, wherein the second signal attenuator exhibits a second attenuation level that is adjusted based on the measured temperature

An aspect of the disclosure provides a radio-frequency front end module. The radio-frequency front end module includes a signal path configured to convey a radio-frequency signal. The radio-frequency front end module includes a power amplifier on the signal path and configured to amplify the radio-frequency signal. The radio-frequency front end module includes first and second signal attenuators on the signal path and communicatively coupled to an input of the power amplifier. The radio-frequency front end module includes a voltage sensor configured to measure a bias voltage used by the power amplifier to amplify the radio-frequency signal. The radio-frequency front end module includes a voltage standing wave ratio (VSWR) sensor on the signal path, coupled to an output of the power amplifier, and configured to measure a VSWR of a load. The first signal attenuator can exhibit a first attenuation level that is adjusted based on the measured bias voltage. The second signal attenuator can exhibit a second attenuation level that is adjusted based on the measured VSWR.

An aspect of the disclosure provides a method of operating wireless circuitry. The method can include transmitting, using a transmitter, a radio-frequency signal over a signal path. The method can include attenuating, using a first signal attenuator on the signal path, the radio-frequency signal by a first attenuation level. The method can include attenuating, using a second signal attenuator on the signal path, the radio-frequency signal by a second attenuation level. The method can include amplifying, using a power amplifier, the radio-frequency signal after attenuation by the first and second signal attenuators. The method can include measuring, using a temperature sensor, a temperature of the power amplifier. The method can include measuring, using an impedance sensor, an impedance of a load communicatively coupled to an output of the power amplifier. The method can include adjusting, using one or more processors, the first attenuation level based on the measured temperature. The method can include adjusting, using the one or more processors, the second attenuation level based on the measured impedance.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers and sensors in accordance with some embodiments.

FIG. 3 is a diagram of illustrative circuitry in an electronic device that may be used to mitigate performance variations in a radio-frequency amplifier across operating conditions in accordance with some embodiments.

FIG. 4 is a flow chart of illustrative operations involved in transmitting radio-frequency signals over a signal path in accordance with some embodiments.

FIG. 5 is a plot of efficiency as a function of output power level for an illustrative radio-frequency amplifier under different biasing conditions in accordance with some embodiments.

### DETAILED DESCRIPTION

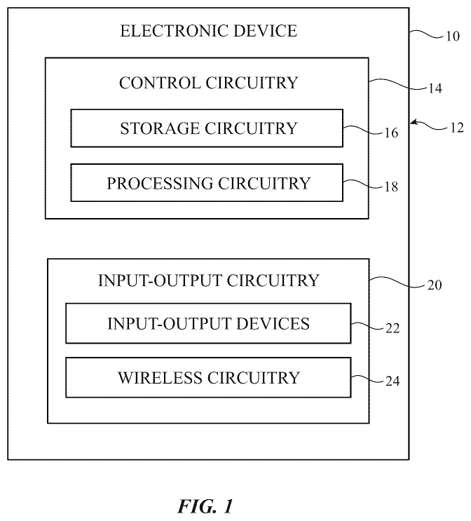

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, satellite communications (satcom) applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), satcom protocols, antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), a satcom band such as an L-band, S-band (e.g., from 2-4 GHz), C-band (e.g., from 4-8 GHz), X-band, Ku-band (e.g., from 12-18 GHz), Ka-band (e.g., from 26-40 GHz), etc., ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, industrial, scientific, and medical (ISM) bands such as an ISM band between around 900 MHz and 950 MHz or other ISM bands below or above 1 GHz, one or more unlicensed bands, one or more bands reserved for emergency and/or public services, and/or any other desired frequency bands of interest.

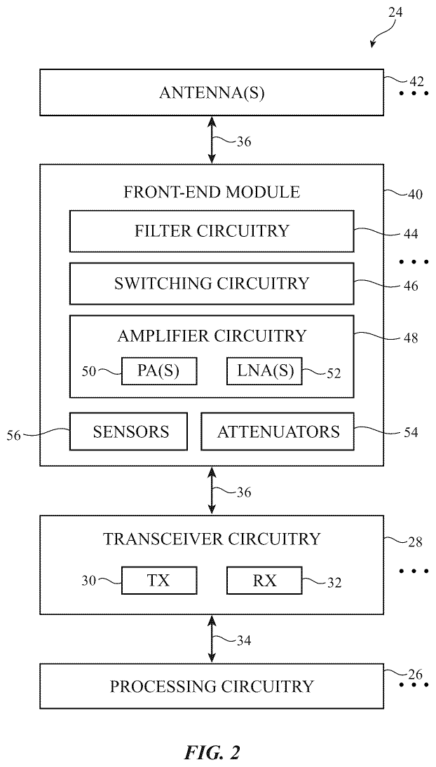

FIG. 2 is a diagram showing illustrative components within wireless circuitry 24. As shown in FIG. 2, wireless circuitry 24 may include processing circuitry such as processing circuitry 26 (e.g., one or more processors), radio-frequency (RF) transceiver circuitry such as radio-frequency transceiver 28, radio-frequency front end circuitry such as radio-frequency front end module (FEM) 40, and antenna(s) 42. Processing circuitry 26 may include a baseband processor or other baseband circuitry, application processor, general purpose processor, microprocessor, microcontroller, digital signal processor, host processor, application specific signal processing hardware, etc. Processing circuitry 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single transceiver 28, a single front end module 40, and a single antenna 42 for the sake of clarity. In general, wireless circuitry 24 may include any desired number of transceivers 28, any desired number of front end modules 40, and any desired number of antennas 42. Each transceiver 28 may include one or more transmitter circuits 30 configured to output uplink signals to antenna 42 and/or may include one or more receiver circuits 32 configured to receive downlink signals from antenna 42. Each transceiver 28 may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide transmit signals (e.g., digital or baseband signals) to transceiver 28 over path 34. Transceiver 28 may further include circuitry for converting the transmit (baseband) signals received from processing circuitry 26. For example, transceiver 28 may include mixer circuitry for up-converting (or modulating) the transmit (baseband) signals to radio frequencies prior to transmission over antenna 42. The example of FIG. 2 in which processing circuitry 26 communicates with transceiver 28 is merely illustrative. In general, transceiver 28 may communicate with a baseband processor, an application processor, general purpose processor, a microcontroller, a microprocessor, or one or more processors within processing circuitry 18 (FIG. 1). Transceiver 28 may also include digital-to-analog converter (DAC) and/or analog-to-digital converter (ADC) circuitry for converting signals between digital and analog domains. Transceiver 28 may use transmitter (TX) 30 to transmit radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40.

Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier (PA) circuits 50 and/or one or more low-noise amplifier circuits 52), signal attenuator circuitry such as one or more signal attenuators 54, sensor circuitry such as one or more sensors 56, impedance matching circuitry (e.g., circuitry that helps to match the impedance of antenna 42 to the impedance of radio-frequency transmission line path 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, some or all of the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, an integrated circuit chip or system-on-chip (SOC), or a flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), a Wi-Fi® 7 band, wireless personal area network (WPAN) transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

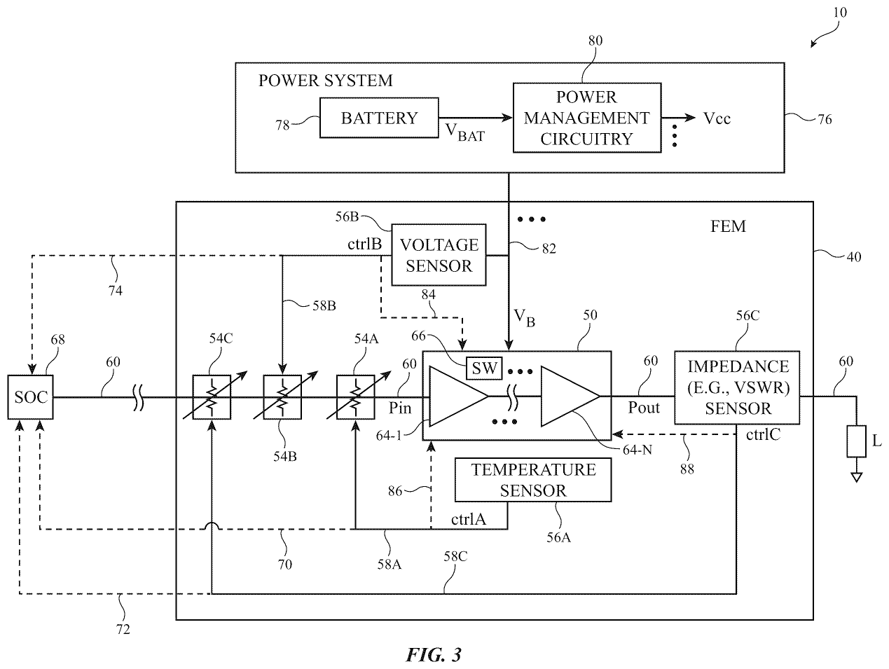

During signal transmission, PA circuits 50 on front end module 40 may amplify radio-frequency signals propagating along a corresponding signal path. FIG. 3 is a circuit diagram showing one example of how a PA circuit 50 may be disposed on a signal path in front end module 40. As shown in FIG. 3, front end module 40 may include a signal path such as signal path 60. Signal path 60 may be a radio-frequency signal path that forms a part of radio-frequency transmission line path 36 of FIG. 2, for example.

A first end of signal path 60 may be communicatively coupled to SOC 68. A second end of signal path 60 may be communicatively coupled to an output load L. SOC 68 may, for example, include a corresponding transceiver 28 (FIG. 2) that transmits radio-frequency signals to output load L over signal path 60. SOC 68 may include, for example, a radio, modem, or transceiver integrated circuit (IC) chip. If desired, SOC 68 may also include baseband circuitry (e.g., in processing circuitry 26 of FIG. 2). Output load L may include a corresponding antenna 42 (FIG. 3). Front end module 40 may include a power amplifier (PA) circuit 50 disposed on signal path 60. PA circuit 50 is sometimes also referred to herein simply as power amplifier 50.

PA circuit 50 may include N PA (gain) stages 64 coupled in series along signal path 60 (e.g., a first PA stage 64-1, an Nth PA stage 64-N, etc.). In a simplest case, PA circuit 50 includes only a single PA stage 64 (e.g., PA stage 64-1). If desired, N may be an integer greater than or equal to two. PA circuit 50 may also include switching circuitry 66. Switching circuitry 66 may be adjusted to selectively activate or deactivate one or more of PA stages 64 at a given time. An active or activated PA stage 64 is sometimes also referred to herein as an enabled PA stage. An enabled PA stage is switched into signal path 60 and actively amplifies a signal transmitted along signal path 60. An inactive or deactivated PA stage 64 is sometimes also referred to herein as a disabled PA stage. A disabled PA stage does not amplify signals transmitted along signal path 60. Instead, the signals on signal path 60 are routed around disabled PA stage(s) by switching circuitry 66. Switching circuitry 66 may include, for example, one or more switches coupled in series along signal path 60 and/or one or more bypass switches that route signal path 60 through enabled PA stage(s) in PA circuit 50 and that route signal path 60 around disabled PA stage(s) in PA circuit 50. Additionally or alternatively, the power supply voltage (e.g., bias voltage V_{B}) may be de-asserted or turned off to disable or deactivate a PA stage and may be asserted or turned on to enable or activate a PA stage.

During signal transmission, SOC 68 may transmit a signal (e.g., a radio-frequency signal) on signal path 60. If desired, the radio-frequency signal may carry wireless data (e.g., symbols, frames, packets, datagrams, etc.). If desired, the radio-frequency signal may carry a spatial ranging waveform (e.g., a radar waveform), a reference signal waveform, or any other desired signal waveform. Signal path 60 may carry the signal to output load L. The signal may be incident upon PA circuit 50 at an input power level Pin. PA circuit 50 may amplify the signal (e.g., applying a non-zero gain to the signal) to output the signal at a corresponding output power level Pout. The gain of PA circuit 50 may be controlled by one or more bias voltages V_{B} received at one or more bias terminals of PA circuit 50 from power system 76 over one or more bias voltage lines 82.

Power system 76 may include a battery 78 of device 10. Battery 78 may output a DC voltage such as battery voltage V_{BAT}. Power system 76 may also include power management circuitry 80 that generates one or more DC power supply voltages such as power supply voltage V_{CC} based on battery voltage V_{BAT}. Power management circuitry 80 may include, for example, step-up converters, step-down converters, low drop out (LDO) regulators, signal attenuators, transformers, and/or any other desired power supply voltage generation circuitry that generates power supply voltage V_{CC} based on battery voltage V_{BAT} (e.g., at voltage levels suitable to power one or more components in device 10). If desired, power management circuitry 80 may also output one or more reference potentials (e.g., a reference voltage V_{SS}) used by one or more components in device 10. The bias voltage V_{B} used to bias PA circuit 50 may include battery voltage V_{BAT} and/or may include power supply voltages V_{CC}.

PA circuit 50 may be operated using an open loop power control (OLPC) scheme (e.g., where the output of PA circuit 50 is not fed back to the input of PA circuit 50 or used to actively adjust the biasing of PA circuit 50 as in a closed loop power control scheme). In practice, power amplifier circuit 50 does not exhibit perfect linearity. As such, power amplifier circuit 50 outputs an amplified signal at output power levels Pout that increase linearly as a function of input power level Pin up until a saturation power Psat of amplifier circuit 50. For input power levels higher than saturation power Psat (sometimes also referred to as the compression point), amplifier circuit 50 becomes saturated and the output power level Pout of the amplified signal falls to a near constant level as input power level Pin increases (e.g., the PA circuit operates in compression rather than exhibiting a linear response). Increasing the magnitude of the bias voltage V_{B} supplied to power amplifier circuit 50 may shift the value of saturation power Psat higher, but this may sacrifice efficiency.

In practice, the performance of PA circuit 50 in amplifying signals along signal path 60 (e.g., saturation power Psat, amplifier linearity, amplifier efficiency, etc.) varies over different operating conditions/environments. For example, variations over time in the bias voltage V_{B} supplied by power system 76 can undesirably shift the saturation power Psat of PA circuit 50 in a manner that causes PA circuit 50 move into a less efficient operating region. In addition, the efficiency of PA circuit 50 and output power level Pout can be affected by temperature variations in front end module 40 because the gain of PA circuit 50 and saturation power Psat vary as a function of temperature. Further, variations in the impedance of output load L can cause saturation power Psat, output power level Pout, and/or the efficiency of PA circuit 50 to vary in a manner that affects performance.

If care is not taken, these variations can cause PA circuit 50 to exhibit non-ideal levels of performance in one or more operating conditions/environments. For example, when operating at maximum efficiency, variation in bias voltage V_{B} can lead to a variation in the saturation power Psat of PA circuit 50. If the PA circuit operates in OLPC with constant input power level Pin, this could lead to variation in output power level Pout, excessive current consumption (which can cause battery 78 to brown out), and/or operating the PA circuit in a less efficient region.

In some implementations, the FEM can include additional DC-DC converters, LDO regulators, envelope tracking circuits, and/or average power tracking circuits to help control the bias voltage supplied the PA circuit to help mitigate these variations. However, these components may not be available to front end module 40 due to cost and/or overhead. In other implementations, the PA circuit can be overdriven to help maintain performance. However, overdriving the PA circuit can generate excessive harmonics in the signal on signal path 60 and/or can introduce excessive signal reflection and ruggedness.

To help optimize the performance of PA circuit 50, front end module 40 may include one or more sensors 56 and one or more signal attenuators 54 that serve to mitigate variations in the operating performance of PA circuit 50 as the operating conditions of front end module 40 and device 10 change over time. As shown in FIG. 3, the signal attenuators 54 in front end module 40 may be disposed on signal path 60 and may be communicatively coupled to the input of PA circuit 50. The signal attenuators 54 in front end module 40 may include at least first signal attenuator 54A, a second signal attenuator 54B, and a third signal attenuator 54C coupled in series on signal path 60 between the output of SOC 68 and the input of PA circuit 50. If desired, there may be no other amplifiers disposed on signal path 60 between signal attenuator 54C and signal attenuator 54A.

Signal attenuators 54A, 54B, and 54C may attenuate the signal transmitted by SOC 68 on signal path 60 prior to the signal reaching PA circuit 50 (e.g., signal attenuators 54A-C may collectively provide the signal to PA circuit 50 at input power level Pin). Signal attenuators 54A-C may each perform a respective amount of attenuation on the signal transmitted to PA circuit 50. Signal attenuators 54A-C may perform different amounts of attenuation or, if desired, two or more of the signal attenuators may perform the same amount of signal attenuation. Signal attenuators 54A-C may be adjustable signal attenuators that are controlled to provide different amounts of signal attenuation over time.

Signal attenuators 54A-C may include any desired signal attenuation circuitry.

For example, signal attenuators 54A-C may include a set of variable resistances (e.g., switchable banks of resistors, switched resistors, resistive transistors, diodes, etc.) arranged in a T-topology (e.g., as a T-type attenuator), a pi-topology (e.g., as a pi-type attenuator), a bridge topology, etc. Signal attenuators 54A-C may be analog signal attenuators or digital signal attenuators (e.g., signal attenuators 54A-C may all be analog signal attenuators, signal attenuators 54A-C may all be digital signal attenuators, or some of signal attenuators 54A-C may be analog signal attenuators whereas others of signal attenuators 54A-C may be digital signal attenuators). The amount of attenuation performed by signal attenuators 54A-C (sometimes also referred to herein as the attenuation level of signal attenuators 54A-C) may be adjusted over time by adjusting one or more of the variable resistances in each signal attenuator (e.g., by switching different resistors in the signal attenuator into or out of use, by tuning the resistance of one or more resistors in the signal attenuator, by adjusting a gate voltage provided to one or more transistors in the signal attenuator, etc.).

Signal attenuator 54A may be coupled in series between signal attenuator 54B and PA circuit 50 and signal attenuator 54B may be coupled in series between signal attenuators 54C and 54A. This is illustrative and non-limiting. In general, signal attenuators 54A-C may be coupled together in any desired order between SOC 68 and PA circuit 50 on signal path 60 (e.g., signal attenuator 54A may be coupled between signal attenuators 54C and 54B, signal attenuator 54C may be coupled between signal attenuators 54A and 54B, etc.). If desired, one or two of signal attenuators 54A, 54B, and 54C may be omitted.

The sensors 56 in front end module 40 may include temperature sensing circuitry such as temperature sensor 56A, voltage sensing circuitry such as voltage sensor 56B, and/or impedance sensing circuitry such as impedance sensor 56C. Impedance sensor 56C may be disposed on signal path 60. Impedance sensor 56C may be coupled in series along signal path 60 between the output of PA circuit 50 and output load L. Temperature sensor 56A may be disposed overlapping or adjacent to PA circuit 50 on front end module 40 if desired. Voltage sensor 56B may be operably coupled to bias voltage line(s) 82.

Each sensor 56 may be communicatively and/or operably coupled to a different respective signal attenuator 54 on signal path 60 over a respective control path 58. For example, temperature sensor 56A may be coupled to signal attenuator 54A over control path 58A. Voltage sensor 56B may be coupled to signal attenuator 54B over control path 58B. Impedance sensor 56C may be coupled to signal attenuator 54C over control path 58C. If desired, control path 58A may also couple temperature sensor 56A to SOC 68 (as shown by arrow 70) and/or to PA circuit 50 (as shown by arrow 86). If desired, control path 58B may also couple voltage sensor 56B to SOC 68 (as shown by arrow 74) and/or to PA circuit 50 (as shown by arrow 84). If desired, control path 58C may also couple impedance sensor 56C to SOC 68 (as shown by arrow 72) and/or to PA circuit 50 (as shown by arrow 88).

Temperature sensor 56A, voltage sensor 56B, and impedance sensor 56C may separately and independently set, configure, control, and/or adjust signal attenuators 54A, 54B, and 54C, respectively, based on the operating conditions of PA circuit 50 and front end module 40. For example, temperature sensor 56A may measure the temperature of one or more locations on front end module 40, PA circuit 50, and/or device 10. Temperature sensor 56A may generate temperature sensor data indicative of the measured temperature. Temperature sensor 56A may generate a control signal ctrlA based on the measured temperature. Temperature sensor 56A may provide control signal ctrlA to signal attenuator 54A over control path 58A. Control signal ctrlA may be an analog control signal or may be a digital control signal. Control path 58A may be an analog control path or a digital control path.

Control signal ctrlA may control (e.g., set or configure) signal attenuator 54A to exhibit a corresponding attenuation level that is selected (e.g., by temperature sensor 56A, control circuitry 14 of FIG. 1, etc.) based on the measured temperature. As one example, temperature sensor 56A may use a look up table (LUT) stored on front end module 40 or elsewhere that maps different measured temperatures to different settings of signal attenuator 54A to generate control signal ctrlA. Control signal ctrlA may adjust the attenuation of signal attenuator 54A over time (e.g., as the measured temperature changes over time). For example, under a constant input power level and OLPC condition, control signal ctrlA may increase the attenuation level of signal attenuator 54A (e.g., decreasing input power level Pin) responsive to a decrease in the measured temperature and/or may decrease the attenuation level of signal attenuator 54A (e.g., increasing input power level Pin) responsive to an increase in the measured temperature. This may, for example, help to mitigate an increase in the saturation power Psat of PA circuit 50 caused by colder operating conditions and/or a decrease in the saturation power Psat of PA circuit 50 caused by warmer operating conditions (for constant input power levels Pin). If desired, signal attenuator 54A may be set in a default state (e.g., calibrated to room temperature) to allow sufficient headroom to increase or decrease signal attenuation as front end module 40 heats and cools over time.

If desired, temperature sensor 56A may use control signal ctrlA to adjust the output power level of SOC 68 based on the measured temperature (e.g., decreasing the output power level responsive to a decrease in the measured temperature and/or increasing the output power level responsive to an increase in the measured temperature). Temperature sensor 56A may perform this adjustment in addition to or instead of adjusting signal attenuator 54A. If desired, temperature sensor 56A may use control signal ctrlA to adjust the number of active PA stages 64 in PA circuit 50 and/or other parameters of PA circuit 50 (e.g., biasing and/or other conditions that affect the output power of the PA circuit) based on the measured temperature (e.g., decreasing the number of active PA stages 64 responsive to a decrease in the measured temperature and/or increasing the number of active PA stages 64 responsive to an increase in the measured temperature). Temperature sensor 56A may perform this adjustment in addition to adjusting signal attenuator 54A, in addition to adjusting SOC 68, in addition to adjusting both signal attenuator 54A and SOC 68, or instead of adjusting signal attenuator 54A and SOC 68.

Consider one example in which the signal transmitted over signal path 60 includes a single long packet. In this example, the temperature sensor may sense changes in temperature across the packet (e.g., between the start and end of the packet). If temperature increases across the packet, front end module 40 may first attempt to compensate for the change by adjusting the bias voltage V_{B} provided to PA circuit 50. Front end module 40 may then adjust signal attenuator 54A to adjust the output power level Pout of PA circuit 50 to mitigate the effect of the temperature change without causing excessive current consumption by the PA circuit. Device 10 may store correlation data (e.g., in one or more LUTs) that instruct front end module 40 on how to adjust bias voltage V_{B} and/or signal attenuator 54A to mitigate changes in the measured temperature.

At the same time, voltage sensor 56B may measure the voltage (e.g., magnitude) of the bias voltage(s) V_{B} supplied to PA circuit 50 over bias voltage line(s) 82. Voltage sensor 56B may include an analog-to-digital converter (ADC), a comparator, a resistive divider, an analog loop, a bandgap reference, and/or any other desired voltage measurement/sensing circuitry. Voltage sensor 56B may generate voltage sensor data indicative of the measured voltage(s). Voltage sensor 56B may generate a control signal ctrlB based on the measured voltage(s). Voltage sensor 56B may provide control signal ctrlB to signal attenuator 54B over control path 58B (e.g., independent of any adjustment to signal attenuator 54A performed based on temperature sensor data gathered by temperature sensor 56A). Control signal ctrlB may be an analog control signal or may be a digital control signal. Control path 58B may be an analog control path or a digital control path.

Control signal ctrlB may control (e.g., set or configure) signal attenuator 54B to exhibit a corresponding attenuation level that is selected (e.g., by voltage sensor 56B, control circuitry 14 of FIG. 1, etc.) based on the measured voltage(s) (e.g., when PA circuit 50 is operating in OLPC). As one example, voltage sensor 56B may use a LUT stored on front end module 40 or elsewhere that maps different measured bias voltages to different settings of signal attenuator 54B to generate control signal ctrlB. Control signal ctrlB may adjust the attenuation of signal attenuator 54B over time (e.g., as the measured bias voltage changes over time).

For example, control signal ctrlB may increase the attenuation level of signal attenuator 54B responsive to a decrease in the measured bias voltage V_{B}. A decrease in bias voltage V_{B} may cause the saturation power Psat of PA circuit 50 to drop and the increase in attenuation by signal attenuator 54B may serve to decrease input power level Pin to compensate (e.g., moving the PA circuit to a lower output power level Pout). As another example, control signal ctrlB may decrease the attenuation level of signal attenuator 54B responsive to an increase in the measured bias voltage V_{B}. An increase in bias voltage V_{B} may cause the saturation power Psat of PA circuit 50 to increase and the decrease in attenuation by signal attenuator 54B may serve to increase input power level Pin to compensate (e.g., moving the PA circuit to its peak efficiency area). In general, the change in saturation power ΔPsat produced by two different magnitudes of bias voltage V_{B} (denoted as V_{B1} and V_{B2}) is given by the equation ΔPsat=20*log₁₀(V_{B2}/V_{B1}). If desired, control signal ctrlB may adjust signal attenuator 54B to limit the output power level Pout of PA circuit 50 responsive to the measured bias voltage falling outside of a predetermined range to avoid excessive current consumption. If desired, signal attenuator 54B may be set in a default state (e.g., calibrated to a typical operating condition) to allow sufficient headroom to increase or decrease signal attenuation as the bias voltage V_{B} output by power system 76 varies over time.

If desired, voltage sensor 56B may use control signal ctrlB to adjust the output power level of SOC 68 based on the measured bias voltage(s) (e.g., decreasing the output power level responsive to a decrease in the measured bias voltage and/or increasing the output power level responsive to an increase in the measured bias voltage). Voltage sensor 56B may perform this adjustment in addition to or instead of adjusting signal attenuator 54A. If desired, voltage sensor 56B may use control signal ctrlB to adjust the number of active PA stages 64 in PA circuit 50 and/or other parameters of PA circuit 50 (e.g., biasing and/or other conditions that affect the output power of the PA circuit) based on the measured bias voltage(s) (e.g., decreasing the number of active PA stages 64 responsive to a decrease in the measured bias voltage and/or increasing the number of active PA stages 64 responsive to an increase in the measured bias voltage). Voltage sensor 56B may perform this adjustment in addition to adjusting signal attenuator 54B, in addition to adjusting SOC 68, in addition to adjusting both signal attenuator 54B and SOC 68, or instead of adjusting signal attenuator 54B and SOC 68.

At the same time, impedance sensor 56C may measure the complex impedance (e.g., phase and/or magnitude) of output load L while signals are transmitted over signal path 60. Impedance sensor 56C may include a signal coupler (e.g., a directional switch coupler, reflectometer, etc.), a power detector, a voltage detector/sensor, a current sensor, a feedback receiver, a voltage standing wave ratio (VSWR) sensor, and/or other impedance measurement circuitry. Impedance sensor 56C is sometimes also referred to as load sensor 56C. Impedance sensor 56C may measure complex impedance values such as scattering parameter values (e.g., S-parameter values such as S11 values, S21 values, etc.) and/or VSWR values associated with output load L, as two examples. Impedance sensor 56C may generate impedance (load) sensor data indicative of the measured impedance. Impedance sensor 56C may generate a control signal ctrlC based on the measured impedance. Impedance sensor 56C may provide control signal ctrlC to signal attenuator 54C over control path 58C (e.g., independent of any adjustment to signal attenuator 54A performed based on temperature sensor data gathered by temperature sensor 56A and independent of any adjustment to signal attenuator 54B performed based on voltage sensor data gathered by voltage sensor 56B). Control signal ctrlC may be an analog control signal or may be a digital control signal. Control path 58C may be an analog control path or a digital control path.

Control signal ctrlC may control (e.g., set or configure) signal attenuator 54C to exhibit a corresponding attenuation level that is selected (e.g., by impedance sensor 56C, control circuitry 14 of FIG. 1, etc.) based on the measured impedance (e.g., when PA circuit 50 is operating in OLPC). As one example, impedance sensor 56C may use a LUT stored on front end module 40 or elsewhere that maps different measured impedances to different settings of signal attenuator 54C to generate control signal ctrlC. Control signal ctrlC may adjust the attenuation of signal attenuator 54C over time (e.g., as the measured impedance of output load L changes over time). This may help to compensate for variations/drift in the saturation power Psat of PA circuit 50 caused by variations in the impedance of output load L (e.g., moving PA circuit 50 back to its optimum region of operation and helping to keep output power level Pout constant despite the change in impedance of output load L). Such variations may occur, for example, when external objects move into or out of place over output load L, thereby changing the loading of output load L and thus the VSWR of output load L. In general, the change in saturation power ΔPsat produced by a change in VSWR of output load L (denoted as ΔVSWR) is given by the relation ΔPsat<20*log₁₀(ΔVSWR).

If desired, impedance sensor 56C may use control signal ctrlC to adjust the output power level of SOC 68 based on the measured impedance of output load L. Impedance sensor 56C may perform this adjustment in addition to or instead of adjusting signal attenuator 54C. If desired, impedance sensor 56C may use control signal ctrlC to adjust the number of active PA stages 64 in PA circuit 50 and/or other parameters of PA circuit 50 (e.g., biasing and/or other conditions that affect the output power of the PA circuit) based on the measured impedance.

Impedance sensor 56C may perform this adjustment in addition to adjusting signal attenuator 54C, in addition to adjusting SOC 68, in addition to adjusting both signal attenuator 54C and SOC 68, or instead of adjusting signal attenuator 54C and SOC 68.

The example of FIG. 3 is illustrative and non-limiting. In general, sensors 56 may include any desired sensors that measure one or more operating conditions that cause the saturation power PSAT of PA circuit 50 to drift over time. Sensors 56 may include more than three different types of sensors that each adjust a different respective signal attenuator 54 (e.g., there may be more than three signal attenuators 54 coupled to the input of PA circuit 50). If desired, voltage sensor 56B, control path 58B, and signal attenuator 54B may be omitted. If desired, impedance sensor 56C, control path 58C, and signal attenuator 54C may be omitted. If desired, temperature sensor 56A, control path 58A, and signal attenuator 54A may be omitted. If desired, voltage sensor 56B, control path 58B, signal attenuator 54B, impedance sensor 56C, control path 58C, and signal attenuator 54C may be omitted. If desired, voltage sensor 56B, control path 58B, signal attenuator 54B, temperature sensor 56A, control path 58A, and signal attenuator 54A may be omitted. If desired, impedance sensor 56C, control path 58C, signal attenuator 54C, temperature sensor 56A, control path 58A, and signal attenuator 54A may be omitted. If desired, the sensor data generated by two or more of sensors 56A, 56B, and 56C may be combined (e.g., using respective scaling factors) and a corresponding control signal may be provided to a single signal attenuator (e.g., any of signal attenuators 54A-54C) to control the attenuation level of that signal attenuator (e.g., any one of signal attenuators 54A-54C may be adjusted based on any desired weighted/scaled combination of temperature sensor data, voltage sensor data, and/or impedance sensor data). In these implementations, a single control path 58 may, if desired, couple two or more of sensors 56A-C to the same signal attenuator. In general, battery 78 may be replaced with any other supply voltage source in device 10 that produces a supply voltage that can vary over time.

The implementation of FIG. 3 in which signal path 60 is a transmit path that transmits signals from SOC 68 to output load L (e.g., antenna 42 of FIG. 2) is illustrative and non-limiting. In general, PA circuit 50 may be replaced with any desired amplifier in device 10, signal path 60 may be any desired signal path, and SOC 68 may be replaced with any desired signal source (e.g., a signal generator, a synthesizer, a transmitter, etc.). In practice, additional radio-frequency components (e.g., switches, filters, amplifiers, mixers, signal couplers, signal splitters, transformers, baluns, matching networks, etc.) may be disposed on signal path 60 if desired, but have been omitted from FIG. 3 for the sake of clarity.

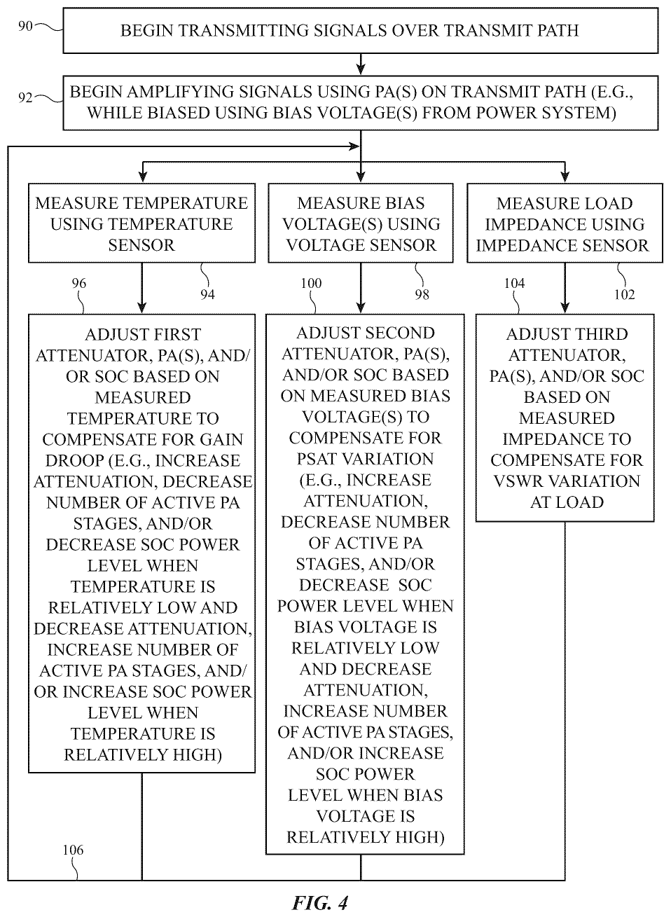

FIG. 4 is a flow chart of operations involved in transmitting a radio-frequency signal over signal path 60 of FIG. 3. At operation 90, SOC 68 (or another signal source) may begin transmitting radio-frequency signals to output load L over signal path 60. Signal attenuators 54A-C may begin attenuating the transmitted radio-frequency signals using initial or default attenuation states or levels.

At operation 92, PA circuit 50 (or another amplifier) may begin amplifying the radio-frequency signals transmitted along signal path 60 while biased using bias voltage(s) V_{B}. Processing may proceed to one or more of operations 94, 98, and 102 in parallel.

At operation 94, temperature sensor 56A may perform one or more temperature measurements.

At operation 96, temperature sensor 56A and/or control circuitry 14 (FIG. 1) may use control signal ctrlA to set and/or adjust the attenuation level of signal attenuator 54A, the output power level of SOC 68, and/or the number of active PA stages 64 in PA circuit 50 based on the temperature measurement(s) (e.g., to compensate for gain droop and/or drift in saturation power Psat caused by variations in operating temperature). For example, signal attenuator 54A may be controlled to perform and/or exhibit a relatively high level of attenuation, SOC 68 may be controlled to exhibit a relatively low output power level, and/or PA circuit 50 may be controlled to activate a relatively low number of PA stages 64 (or to deactivate a relatively high number of PA stages 64) if/when the measured temperature is relatively low (e.g., less than a first threshold temperature, within a first temperature range, etc.).

As another example, signal attenuator 54A may be controlled to perform and/or exhibit a relatively low level of attenuation, SOC 68 may be controlled to exhibit a relatively high output power level, and/or PA circuit 50 may be controlled to activate a relatively high number of PA stages 64 (or to deactivate a relatively low number of PA stages 64) if/when the measured temperature is relatively high (e.g., greater than a second threshold temperature, within a second temperature range higher than the first temperature range, etc.). Operation 98 and/or operation 100 may be performed prior to, after, or concurrent with operation 94 and/or operation 96.

At operation 98, voltage sensor 56B may perform one or more voltage measurements of bias voltage V_{B} (sometimes also referred to herein as bias voltage measurements).

At operation 100, voltage sensor 56B and/or control circuitry 14 (FIG. 1) may use control signal ctrlB to adjust the attenuation level of signal attenuator 54B, the output power level of SOC 68, and/or the number of active PA stages 64 in PA circuit 50 based on the bias voltage measurement(s) (e.g., to compensate for variation in saturation power Psat caused by variation in bias voltage V_{B} as output by the power system). For example, signal attenuator 54B may be controlled to perform and/or exhibit a relatively high level of attenuation, SOC 68 may be controlled to exhibit a relatively low output power level, and/or PA circuit 50 may be controlled to activate a relatively low number of PA stages 64 (or to deactivate a relatively high number of PA stages 64) if/when the measured bias voltage is relatively low (e.g., less than a first threshold voltage, within a first voltage range, etc.).

As another example, signal attenuator 54B may be controlled to perform and/or exhibit a relatively low level of attenuation, SOC 68 may be controlled to exhibit a relatively high output power level, and/or PA circuit 50 may be controlled to activate a relatively high number of PA stages 64 (or to deactivate a relatively low number of PA stages 64) if/when the measured bias voltage is relatively high (e.g., greater than a second threshold voltage, within a second voltage range higher than the first voltage range, etc.). Operation 102 and/or operation 104 may be performed prior to, after, or concurrent with operation 94, operation 96, operation 98, and/or operation 100.

At operation 102, impedance sensor 56C may perform one or more impedance measurements of output load L (e.g., VSWR measurements, S-parameter measurements, etc.).

At operation 104, impedance sensor 56C and/or control circuitry 14 (FIG. 1) may use control signal ctrlC to adjust the attenuation level of signal attenuator 54C, the output power level of SOC 68, and/or the number of active PA stages 64 in PA circuit 50 based on the impedance measurement(s) (e.g., to move PA circuit 50 back to its maximum efficiency region, compensating for variations in VSWR at output load L).

Processing may loop back to operations 94-102 via path 106 to continue to update signal attenuator(s) 54, PA circuit 50, and/or SOC 68 to adjust PA circuit 50 in a manner that compensates for changes in the operating conditions of front end module 40 and device 10 over time. The example of FIG. 4 is illustrative and non-limiting. If desired, operations 94-96 may be omitted, operations 98-100 may be omitted, operations 102-104 may be omitted, operations 94-100 may be omitted, operations 98-104 may be omitted, or operations 94, 96, 102, and 104 may be omitted. Operations 94-96, operations 98-100, and operations 102-104 may be independently triggered (e.g., by respective trigger conditions, which can occur at different times or at the same time) and may independently loop back over path 106. Put differently, processing may independently iterate over operations 94-96, 98-100, and 102-104 responsive to any desired trigger conditions and/or at different times.

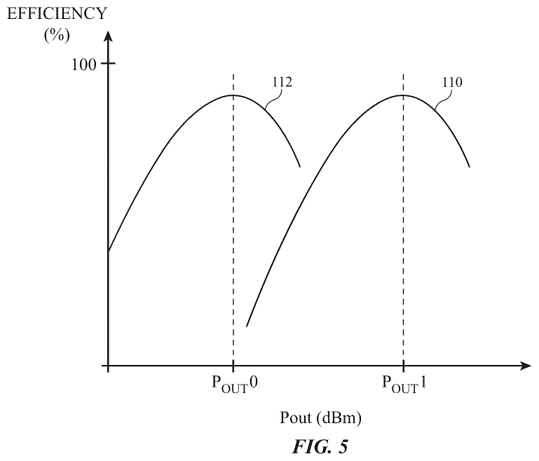

FIG. 5 plots the efficiency of PA circuit 50 as a function of its output power level Pout under different biasing conditions. Curve 110 plots the efficiency of PA circuit 50 while biased using a first bias voltage V_{B}. As shown by curve 110, PA circuit 50 exhibits peak efficiency at a first output power level P_{OUT}1 when biased using the first bias voltage. Curve 112 plots the efficiency of PA circuit 50 while biased using a second bias voltage V_{B}. As shown by curve 112, PA circuit 50 exhibits peak efficiency at a first output power level P_{OUT}0 when biased using the second bias voltage. As shown by curves 110 and 112, varying bias voltage V_{B} effectively moves the peak efficiency region of PA circuit 50 between output power levels P_{OUT}1 and P_{OUT}0 without substantially reducing the peak efficiency of the PA circuit. By performing the operations of FIG. 4, front end module 40 may move PA circuit 50 move back to its peak efficiency region given its present bias voltage V_{B} (as well as its present temperature, VSWR, etc.).

The methods and operations described above in connection with FIGS. 1-5 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. Wireless circuitry comprising:
a signal source;
an output load;
a signal path that couples the signal source to the output load, the signal source being configured to transmit a radio-frequency signal to the output load over the signal path;
an amplifier on the signal path and configured to amplify the radio-frequency signal;
first and second signal attenuators on the signal path between the signal source and the amplifier;
a voltage sensor configured to measure a bias voltage of the amplifier, wherein the first signal attenuator exhibits a first attenuation level that is adjusted based on the measured bias voltage; and
a temperature sensor configured to measure a temperature of the amplifier, wherein the second signal attenuator exhibits a second attenuation level that is adjusted based on the measured temperature.

2. The wireless circuitry of claim 1, further comprising:
an impedance sensor disposed on the signal path between the amplifier and the output load; and
a third signal attenuator on the signal path and coupled in series with the first and second signal attenuators between the signal source and the amplifier, wherein the impedance sensor is configured to measure an impedance of the output load and the third signal attenuator exhibits a third attenuation level that is adjusted based on the measured impedance.

3. The wireless circuitry of claim 1, wherein the first signal attenuator is coupled in series between the second signal attenuator and the signal source.

4. The wireless circuitry of claim 1, wherein the second signal attenuator is coupled in series between the first signal attenuator and the signal source.

5. The wireless circuitry of claim 1, wherein the signal source comprises a radio-frequency transmitter and the output load comprises an antenna.

6. The wireless circuitry of claim 5, further comprising:
a system-on-chip (SOC) that includes the radio-frequency transmitter; and
a front end module that includes the amplifier, the first and second signal attenuators, the voltage sensor, and the temperature sensor.

7. The wireless circuitry of claim 6, wherein the SOC exhibits an output power level that is adjusted based on the measured temperature or the measured bias voltage.

8. The wireless circuitry of claim 1, wherein the bias voltage comprises a direct current voltage output by a battery.

9. The wireless circuitry of claim 1, wherein the bias voltage comprises a power supply voltage generated based on a direct current voltage output by a battery.

10. The wireless circuitry of claim 1, wherein the voltage sensor is configured to increase the first attenuation level responsive to a reduction in the measured bias voltage and is configured to decrease the first attenuation level responsive to an increase in the measured bias voltage.

11. The wireless circuitry of claim 10, wherein the temperature sensor is configured to increase the second attenuation level responsive to a decrease in the measured temperature and is configured to decrease the second attenuation level responsive to an increase in the measured temperature.

12. The wireless circuitry of claim 1, wherein the temperature sensor is configured to increase the second attenuation level responsive to a decrease in the measured temperature and is configured to decrease the second attenuation level responsive to an increase in the measured temperature.

13. The wireless circuitry of claim 1, wherein the amplifier comprises:
a set of power amplifier stages; and
switching circuitry coupled to the set of power amplifier stages, wherein the switching circuitry is configured to adjust a number of active power amplifier stages in the set of power amplifier stages based on the measured temperature or the measured bias voltage.

14. A radio-frequency front end module comprising:
a signal path configured to convey a radio-frequency signal;
a power amplifier on the signal path and configured to amplify the radio-frequency signal;
first and second signal attenuators on the signal path and communicatively coupled to an input of the power amplifier;
a voltage sensor configured to measure a bias voltage used by the power amplifier to amplify the radio-frequency signal; and
a voltage standing wave ratio (VSWR) sensor on the signal path, coupled to an output of the power amplifier, and configured to measure a VSWR of a load, wherein
the first signal attenuator exhibits a first attenuation level that is adjusted based on the measured bias voltage, and
the second signal attenuator exhibits a second attenuation level that is adjusted based on the measured VSWR.

15. The radio-frequency front end module of claim 14, further comprising:
a third attenuator coupled in series with the first and second signal attenuators on the signal path and communicatively coupled to the input of the power amplifier; and
a temperature sensor configured to measure a temperature of the radio-frequency front end module, wherein the third signal attenuator exhibits a third attenuation level that is adjusted based on the measured temperature.

16. The radio-frequency front end module of claim 15, further comprising:
a first control path that couples the voltage sensor to the first signal attenuator;
a second control path that couples the impedance sensor to the second signal attenuator;
a third control path that couples the temperature sensor to the third signal attenuator; and
a bias voltage path coupled to a bias terminal of the power amplifier, wherein the voltage sensor is coupled to the bias voltage path.

17. The radio-frequency front end module of claim 16, wherein:
the voltage sensor is configured to transmit a first control signal to the first signal attenuator over the first control path that increases the first attenuation level responsive to a reduction in the measured bias voltage and that decreases the first attenuation level responsive to an increase in the measured bias voltage;
the impedance sensor is configured to transmit a second control signal to the second signal attenuator over the second control path that adjusts the second attenuation level responsive to a change in the measured impedance; and
the temperature sensor is configured to transmit a third control signal to the third signal attenuator over the third control path that increases the third attenuation level responsive to a decrease in the measured temperature and that decreases the third attenuation level responsive to an increase in the measured temperature.

18. A method of operating wireless circuitry comprising:
transmitting, using a transmitter, a radio-frequency signal over a signal path;
attenuating, using a first signal attenuator on the signal path, the radio-frequency signal by a first attenuation level;
attenuating, using a second signal attenuator on the signal path, the radio-frequency signal by a second attenuation level;
amplifying, using a power amplifier, the radio-frequency signal after attenuation by the first and second signal attenuators;
measuring, using a temperature sensor, a temperature of the power amplifier;
measuring, using an impedance sensor, an impedance of a load communicatively coupled to an output of the power amplifier;
adjusting, using one or more processors, the first attenuation level based on the measured temperature; and
adjusting, using the one or more processors, the second attenuation level based on the measured impedance.

19. The method of claim 18, wherein adjusting the first attenuation level comprises:
increasing the first attenuation level responsive to a decrease in the measured temperature; and
decreasing the first attenuation level responsive to an increase in the measured temperature.

20. The method of claim 19, further comprising:
attenuating, using a third signal attenuator on the signal path, the radio-frequency signal by a third attenuation level;
measuring, using a voltage sensor, a bias voltage used by the amplifier to amplify the radio-frequency signal;
increasing, using the one or more processors, the third attenuation level responsive to a decrease in the measured bias voltage; and
decreasing, using the one or more processors, the third attenuation level responsive to an increase in the measured bias voltage.
